(19) United States
(12) Patent Application Publication
(10) Pub. No.: US 2026/0338991 A1
(43) Pub. Date: Oct. 29, 2026

(54) OPTICAL FILM WITH IMPROVED ELASTIC HYSTERESIS

(71) Applicant: KOLON INDUSTRIES, INC., Seoul (KR)

(72) Inventors: Jong Won YANG, Seoul (KR); Kyung Wook KWON, Seoul (KR); Hyo Jun PARK, Seoul (KR)

(21) Appl. No.: 19/107,735

(22) PCT Filed: Sep. 25, 2023
(86) PCT No.: PCT/KR2023/014668

§ 371 Date: Feb. 28, 2025

(30) Foreign Application Priority Data
Sep. 29, 2022 (KR) 10-2022-0124101
Sep. 22, 2023 (KR) 10-2023-0127122

(51) Int. Cl. G02B 1/04

(52) U.S. Cl. CPC G02B 1/04

(57) ABSTRACT

Provided are an optical film and a display device comprising same, the optical film according to an embodiment of the present invention comprising a light-transmissive matrix, and a filler dispersed therein, and having S/S index of 0.6 or greater.

### TECHNICAL FIELD

The present disclosure relates to an optical film and a display device including the same and more particularly, to an optical film having excellent mechanical properties.

### BACKGROUND ART

Recently, the use of an optical film instead of glass as a cover window of a display device has been considered with the goal of reducing thickness and weight and increasing the flexibility of the display device. In order for the optical film to be usable as a cover window of a display device, the optical film needs to have superior optical properties and excellent mechanical properties. For example, an optical film needs to have properties such as excellent strength, hardness, abrasion resistance, and flexibility.

Fillers may be added in order to impart desired physical properties to an optical film requiring various physical properties. The fillers may vary depending on physical properties required for the optical film.

### DISCLOSURE

### Technical Problem

Therefore, the present disclosure has been made in view of the above problems, and it is one aspect of the present disclosure to provide an optical film that includes a fiber- or filament-shaped filler dispersed in a light-transmitting matrix.

It is another aspect of the present disclosure to provide an optical film having an S/S index of 0.6 or more.

It is another aspect of the present disclosure to provide an optical film having a yield tensile strength of 90 to 160 MPa.

It is another aspect of the present disclosure to provide an optical film having a modulus of 4.0 to 15 GPa.

It is another aspect of the present disclosure to provide an optical film having restoring force. The optical film according to the present disclosure has restoring force and may be useful for display devices.

It is another aspect of the present disclosure to provide a display device including the optical film.

### Technical Solution

In accordance with one aspect of the present disclosure, provided is an optical film including a light-transmitting matrix, and a filler dispersed in the light-transmitting matrix, the optical film having an S/S index of 0.6 or more, wherein the S/S index is calculated in accordance with Equation 1 below:

S/S index=stress hysteresis/strain hysteresis [Equation 1]
wherein the stress hysteresis is calculated in accordance with Equation 2 below:

Stress hysteresis=[maximum compressive load/total load]×100 [Equation 2]
wherein the strain hysteresis is calculated in accordance with Equation 3 below:

Strain hysteresis=[strain 2−strain 1]×100 [Equation 3]
wherein the maximum compressive load is a maximum compressive load required for the optical film to return to an original state after elongation, and
the total load (N) is a sum of tensile load and compressive load,
wherein the tensile load is a load required for the optical film to be elongated to a specific strain, and
the compressive load is a load required for the optical film to return to an original state after elongation,
the strain 1 is a strain before the optical film is deformed, and
the strain 2 is a strain after the optical film is deformed.

In accordance with another aspect of the present disclosure, provided is a display device including a display panel and the optical film disposed on the display panel.

### Advantageous Effects

According to one embodiment of the present disclosure, the filler included in the optical film has a fiber or filament shape, thus improving the mechanical strength, in particular, the yield tensile strength and elasticity, of the optical film. As a result, resilience (restoring force) can be improved when the optical film according to an embodiment of the present disclosure is used in a display device.

According to one embodiment of the present disclosure, when the S/S index of the optical film is high, hysteresis is improved, less marks are formed upon folding of the optical film, and the restoring force of the film to return to the original state is greater when the film is pressed with the same force.

### DESCRIPTION OF DRAWINGS

FIG. 1 is a schematic diagram illustrating an optical film according to an embodiment of the present disclosure.

FIG. 2 is a cross-sectional view illustrating a part of a display device according to another embodiment of the present disclosure.

FIG. 3 is an enlarged cross-sectional view illustrating part “P” in FIG. 2.

### BEST MODE

Hereinafter, embodiments of the present disclosure will be described in detail with reference to the accompanying drawings. However, the following embodiments are illustratively provided merely for clear understanding of the present disclosure and do not limit the scope of the present disclosure.

The shapes, sizes, ratios, angles, and numbers disclosed in the drawings for describing embodiments of the present disclosure are merely examples, and the present disclosure is not limited to the illustrated details. Like reference numerals refer to like elements throughout the present specification. In the following description, when a detailed description of relevant known functions or configurations is determined to unnecessarily obscure important points of the present disclosure, the detailed description will be omitted.

In the case in which a term such as “comprise”, “have”, or “include” is used in the present specification, another part may also be present, unless “only” is also used. Terms in a singular form may include the plural meanings, unless noted to the contrary. Also, in construing an element, the element is to be construed as including an error range, even if there is no explicit description thereof.

In describing a positional relationship, for example, when the positional relationship is described using “on”, “above”, “below”, or “next to”, the case of no contact therebetween may be included, unless “immediately” or “directly” is used.

Spatially relative terms, such as “below”, “beneath”, “lower”, “above”, and “upper”, may be used herein to describe the relationship between a device or element and another device or element, as shown in the figures. It will be understood that spatially relative terms are intended to encompass different orientations of a device during the use or operation of the device, in addition to the orientation depicted in the figures. For example, if a device in one of the figures is turned upside down, elements described as “below” or “beneath” other elements would then be positioned “above” the other elements. The exemplary term “below” or “beneath” can, therefore, encompass the meanings of both “below” and “above”. In the same manner, the exemplary term “above” or “upper” can encompass the meanings of both “above” and “below”.

In describing temporal relationships, for example, when a temporal order is described using “after”, “subsequent”, “next”, or “before”, the case of a non-continuous relationship may be included, unless “immediately” or “directly” is used.

It will be understood that, although the terms “first”, “second”, etc. may be used herein to describe various elements, these elements are not limited by these terms. These terms are only used to distinguish one element from another. Therefore, a first element could be termed a second element within the technical idea of the present disclosure.

It should be understood that the term “at least one” includes all combinations related with one or more items. For example, “at least one among a first element, a second element, and a third element” may include all combinations of two or more elements selected from among the first, second, and third elements, as well as each of the first, second, and third elements.

Features of various embodiments of the present disclosure may be partially or completely integrated or combined with each other, and may be variously interoperated with each other and driven technically. The embodiments of the present disclosure may be carried out independently from each other, or may be carried out together in an interrelated manner.

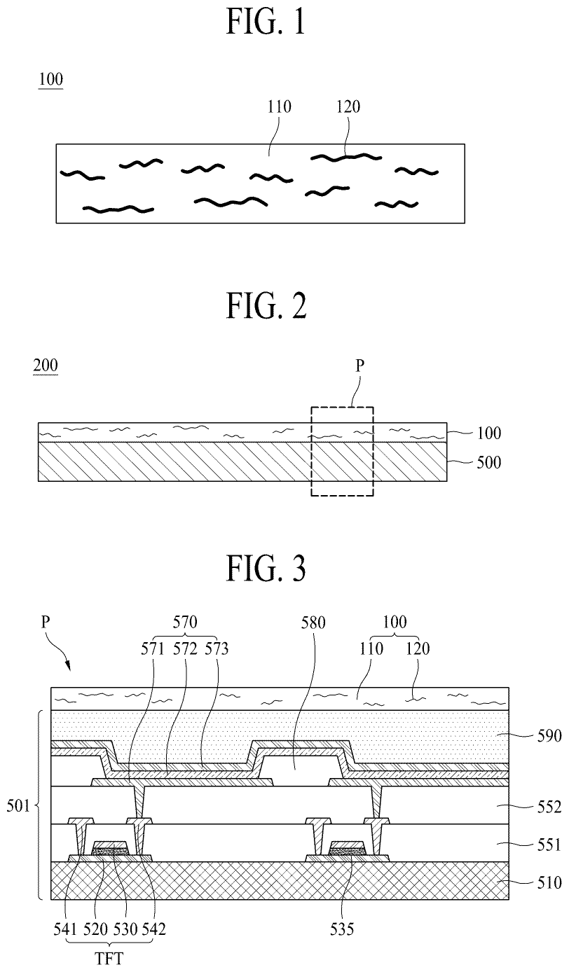

FIG. 1 is a schematic diagram illustrating an optical film 100 according to an embodiment of the present disclosure. According to one embodiment of the present disclosure, a film having light transmittance is referred to as an “optical film 100”.

The optical film 100 according to an embodiment of the present disclosure includes a light-transmitting matrix 110 and a filler 120 dispersed in the light-transmitting matrix 110.

The light-transmitting matrix 110 may be light-transmissive. According to an embodiment of the present disclosure, the light-transmitting matrix 110 may be flexible. For example, the optical film according to an embodiment of the present disclosure may be bendable, foldable, or rollable. As a result, the optical film 100 according to an embodiment of the present disclosure may be light-transmissive and may be bendable, foldable, or rollable.

According to an embodiment of the present disclosure, the light-transmitting matrix 110 may include at least one of an imide repeating unit or an amide repeating unit.

The light-transmitting matrix 110 according to an embodiment of the present disclosure may be produced from monomeric ingredients including dianhydrides and diamines. Specifically, the light-transmitting matrix 110 may include an imide repeating unit formed by dianhydride and diamine.

However, the light-transmitting matrix 110 according to an embodiment of the present disclosure is not limited thereto, and the light-transmitting matrix 110 may be produced from monomeric ingredients including a dicarbonyl compound in addition to dianhydride and diamine. The light-transmitting matrix 110 according to an embodiment of the present disclosure may have an imide repeating unit and an amide repeating unit. For example, the light-transmitting matrix 110 having an imide repeating unit and an amide repeating unit may be a polyamide-imide resin.

According to one embodiment of the present disclosure, the light-transmitting matrix 110 may include a polyimide-based polymer. Examples of the polyimide-based polymer may include polyimide polymers, polyamide-imide polymers and the like. The light-transmitting matrix 110 according to an embodiment of the present disclosure may be produced from, for example, a polyimide-based polymer resin.

The light-transmitting matrix 110 may have a thickness sufficient for the optical film 100 to protect the display panel. For example, the light-transmitting matrix 110 may have a thickness of 10 to 100 μm. The thickness of the light-transmitting matrix 110 may be the same as that of the optical film 100.

According to one embodiment of the present disclosure, the aspect ratio of the filler 120 may range from 5 to 2,500. The aspect ratio refers to a ratio of the length to the diameter of the filler 120.

When the aspect ratio of the filler 120 is less than 5, the filler 120 is not long enough and cannot sufficiently perform the function of linking the polymer chains to each other and thus cannot sufficiently exert the function of improving the stability and arrangement characteristics of the polymer chains.

When the aspect ratio of the filler 120 is greater than 2,500, the filler 120 may reduce the dispersibility of the filler 120 and cause agglomeration of the filler 120 within the light-transmitting matrix 110 due to excessively great length. As a result, the optical film 100 may have decreased light transmittance, increased haze and deteriorated optical properties. In addition, the mechanical strength of the optical film 100 may decrease in the area where agglomeration of the filler 120 occurs, and as a result, the modulus of the optical film 100 may decrease and the mechanical strength of the optical film 100 may also decrease.

According to one embodiment of the present disclosure, the length of the filler 120 may range from 0.1 to 5 μm.

When the length of the filler 120 is less than 0.1 μm, the function of the filler 120 to link the polymer chains may not be sufficiently exerted.

When the length of the filler 120 is higher than 5 μm, the dispersibility of the filler 120 may decrease, and as a result, agglomeration of the filler 120 may occur within the light-transmitting matrix 110 and gelation may readily occur due to interaction with the polymer chains. Accordingly, the optical film 100 may have decreased light transmittance, increased haze and deteriorated optical properties.

According to one embodiment of the present disclosure, the diameter of the filler 120 may range from 2 to 20 nm. The diameter is measured in a direction perpendicular to the longitudinal direction.

When the diameter of the filler 120 is less than 2 nm, the stability of the filler 120 may decrease and the filler may be cut or broken, thus contaminating the optical film 100 and increasing the haze of the optical film 100.

When the diameter of the filler 120 is higher than 20 nm, the filler 120 has difficulty in having a wire shape and the optical film 100 may have deteriorated function of linking polymer chains, increased haze, and decreased light transmittance.

There is no particular limitation on the type of filler 120. Any filler may be used without limitation as the filler 120 according to an embodiment of the present disclosure so long as it has a fiber shape. The filler 120 may be inorganic or organic. The filler 120 may include at least one of inorganic fibers, organic fibers, or organic-inorganic hybrid fibers.

More specifically, the filler 120 may have a fiber or filament shape. For example, the filler 120 may have a single-stranded fiber shape, a multi-stranded fiber shape, or a branch shape in which multiple strands are arranged in the form of branches based on one central strand.

According to one embodiment of the present disclosure, the filler 120 may include at least one of glass fiber, aluminum fiber, or fluoride fiber.

The glass fiber contains SiO₂ and may further contain other components in addition to SiO₂. The aluminum fiber contains Al₂O₃ and may further contain other components in addition to Al₂O₃. The fluoride fiber may contain at least one of polytetrafluoroethylene (PTFE) or polyvinylidene fluoride (PVDF), and may further contain other components in addition to PTFE and PVDF.

According to one embodiment of the present disclosure, the filler 120 may include at least one of aluminum oxide hydroxide, SiO₂, Al₂O₃, polytetrafluoroethylene (PTFE), or polyvinylidene fluoride (PVDF).

According to one embodiment of the present disclosure, the filler 120 may be surface-treated. For example, the filler 120 may be fiber surface-treated with an organic compound having an alkoxy group.

According to one embodiment of the present disclosure, the aluminum fiber may include at least one of aluminum oxide hydroxide or Al₂O₃. Aluminum oxide hydroxide is also called “Boehmite” and can be represented by γ-AlO(OH). More specifically, alumina oxide hydroxide may include a structure represented by any of the following Formulas 1, 2, and 3.

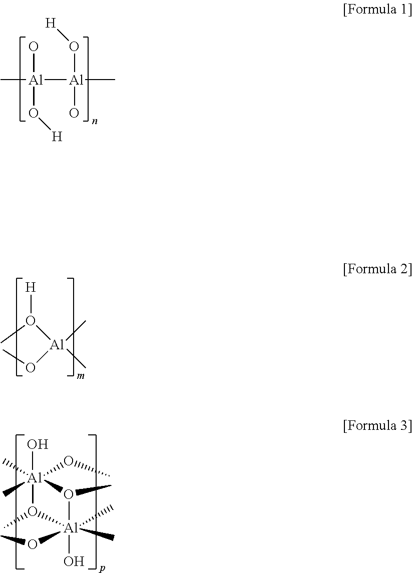

wherein n ranges from 100 to 20,000, m ranges from 50 to 10,000, and p ranges from 50 to 10,000.

When the structures of Formulas 1, 2 and 3 are expanded for better understanding of the structure of the filler 120, the filler 120 may be represented by any one of Formulas 4, 5 and 6.

The structure represented by Formula 1 may be represented by, for example, Formula 4 below. Formula 4 below corresponds to the structure of Formula 1 wherein n is 3.

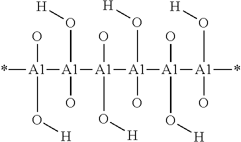

The structure represented by Formula 2 may be represented by, for example, Formula 5 below. Formula 5 below corresponds to the structure of Formula 2 wherein m is 4.

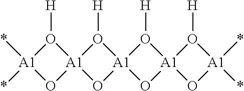

The structure represented by Formula 3 may be represented by, for example, Formula 6 below. Formula 6 below corresponds to the structure of Formula 3 wherein p is 5.

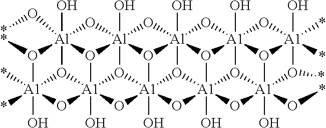

In Formulas 4 to 6, “*” represents a binding position.

According to an embodiment of the present disclosure, Al₂O₃ may have a unit structure represented by Formula 7 below.

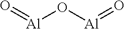

According to an embodiment of the present disclosure, SiO₂ may have a unit structure represented by Formula 8 below.

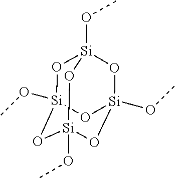

According to an embodiment of the present disclosure, the filler 120 may cause appropriate light scattering to improve the optical properties of the optical film 100. To enhance the light scattering effect, the content of the filler 120 in the optical film 100 may be adjusted.

According to one embodiment of the present disclosure, the content of the filler 120 may be 3 to 50 PHR, with respect to 100 g of the light-transmitting matrix 110. More specifically, the content of the filler 120 may be adjusted to 4 to 30 PHR, or may be 5 to 20 PHR, with respect to 100 g of the light-transmitting matrix 110.

When the content of the filler 120 is less than 3 PHR with respect to 100 g of the light-transmitting matrix 110, the light scattering effect by the filler 120 is insufficient and, as such, the effect of improving the light transmittance of the optical film 100 cannot be obtained and the filler 120 cannot sufficiently exert the function of linking the polymer chains.

On the other hand, when the content of the filler 120 is higher than 50 PHR with respect to 100 g of the light-transmitting matrix 110, the dispersibility of the filler 120 may decrease, the haze of the optical film 100 may decrease, brittleness may increase, agglomeration of the filler 120 may occur due to the excessive amount of the filler 120, and the agglomerated filler 120 blocks light, which may reduce the light transmittance of the optical film 100.

FIG. 2 is a cross-sectional view illustrating a part of a display device 200 according to another embodiment of the present disclosure and FIG. 3 is an enlarged cross-sectional view of “P” in FIG. 2.

Referring to FIG. 2, the display device 200 according to another embodiment of the present disclosure includes a display panel 501 and an optical film 100 on the display panel 501.

Referring to FIGS. 2 and 3, the display panel 501 includes a substrate 510, a thin film transistor TFT on the substrate 510, and an organic light-emitting device 570 connected to the thin film transistor TFT. The organic light-emitting device 570 includes a first electrode 571, an organic light-emitting layer 572 on the first electrode 571, and a second electrode 573 on the organic light-emitting layer 572. The display device 200 shown in FIGS. 2 and 3 is an organic light-emitting display device.

The substrate 510 may be formed of glass or plastic. Specifically, the substrate 510 may be formed of plastic such as a polyimide-based resin or an optical film. Although not shown, a buffer layer may be disposed on the substrate 510.

The thin film transistor TFT is disposed on the substrate 510. The thin film transistor TFT includes a semiconductor layer 520, a gate electrode 530 that is insulated from the semiconductor layer 520 and at least partially overlaps the semiconductor layer 520, a source electrode 541 connected to the semiconductor layer 520, and a drain electrode 542 that is spaced apart from the source electrode 541 and is connected to the semiconductor layer 520.

Referring to FIG. 3, a gate insulating layer 535 is disposed between the gate electrode 530 and the semiconductor layer 520. An interlayer insulating layer 551 may be disposed on the gate electrode 530, and the source electrode 541 and the drain electrode 542 may be disposed on the interlayer insulating layer 551.

A planarization layer 552 is disposed on the thin film transistor TFT to planarize the top of the thin film transistor TFT.

A first electrode 571 is disposed on the planarization layer 552. The first electrode 571 is connected to the thin film transistor TFT through a contact hole provided in the planarization layer 552.

A bank layer 580 is disposed on the planarization layer 552 in a part of the first electrode 571 to define pixel areas or light-emitting areas. For example, the bank layer 580 is disposed in the form of a matrix at the boundaries between a plurality of pixels to define the respective pixel regions.

The organic light-emitting layer 572 is disposed on the first electrode 571. The organic light-emitting layer 572 may also be disposed on the bank layer 580. The organic light-emitting layer 572 may include one light-emitting layer, or two or more light-emitting layers stacked in a vertical direction. Light having any one color among red, green, and blue may be emitted from the organic light-emitting layer 572, and white light may be emitted therefrom.

The second electrode 573 is disposed on the organic light-emitting layer 572.

The first electrode 571, the organic light-emitting layer 572, and the second electrode 573 may be stacked to constitute the organic light-emitting device 570.

Although not shown, when the organic light-emitting layer 572 emits white light, each pixel may include a color filter for filtering the white light emitted from the organic light-emitting layer 572 based on a particular wavelength. The color filter is formed on the light path.

A thin-film encapsulation layer 590 may be disposed on the second electrode 573. The thin-film encapsulation layer 590 may include at least one organic layer and at least one inorganic layer, and the at least one organic layer and the at least one inorganic layer may be alternately disposed.

The optical film 100 is disposed on the display panel 501 having the stack structure described above. The optical film 100 includes a light-transmitting matrix 110 and a filler 120 dispersed in the light-transmitting matrix 110.

According to one embodiment of the present disclosure, the S/S index of the optical film 100 is 0.6 or more and is calculated in accordance with Equation 1 below.

S/S index=stress hysteresis/strain hysteresis [Equation 1]
wherein the stress hysteresis is calculated in accordance with Equation 2 below:

Stress hysteresis=[maximum compressive load/total load]×100 [Equation 2]
wherein the strain hysteresis is calculated in accordance with Equation 3 below:

Strain hysteresis=[strain 2−strain 1]×100 [Equation 3]
wherein the maximum compressive load is a maximum compressive load required for the optical film to return to an original state after elongation, and
the total load (N) is a sum of tensile load and compressive load,
wherein the tensile load is a load required for the optical film to be elongated to a specific strain, and
the compressive load is a load required for the optical film to return to an original state after elongation,
the strain 1 is a strain before the optical film is deformed, and
the strain 2 is a strain after the optical film is deformed.

When the S/S index is less than 0.6, hysteresis of the optical film may not be improved. As a result, when the optical film is folded, it may leave marks, and when the film is pressed with the same force, the force to return to the original state may be reduced.

The optical film 100 according to an embodiment of the present disclosure may have a yield tensile strength of 90 to 160 MPa. More specifically, the optical film 100 may have a yield tensile strength of 100 to 150 MPa and may have a yield tensile strength of 120 to 145 MPa.

When the yield tensile strength of the optical film 100 is less than 90 MPa, the optical film may be vulnerable to deformation due to low yield point and low energy in the elastic section. As a result, the restoration force may be weak when the film is folded or pressed.

The optical film 100 according to an embodiment of the present disclosure may have a modulus of 4.0 to 15 GPa. More specifically, the optical film 100 may have a modulus of 6 to 13 GPa and may also have a modulus of 8 to 12 GPa.

When the modulus of the optical film 100 is less than 4.0 GPa, it may be easily scratched or deformed by external force due to low hardness and may be vulnerable to deformation due to low yield point and low energy in the elastic section. As a result, the restoration force may be weak when the film is folded or pressed.

When the modulus of the optical film 100 is greater than 15 GPa, the optical film 100 may be readily deformed due to external force, which may cause the optical film 100 to be bent. Also, the difference in drag between the optical film 100 and other materials increases, thus resulting in separation or folding between the optical film 100 and other materials when the display device 200 is folded.

Hereinafter, a method of manufacturing an optical film 100 according to another embodiment of the present disclosure will be described.

The method of manufacturing an optical film 100 according to an embodiment of the present disclosure includes primarily dispersing the filler 120 in a resin solution for forming a light-transmitting matrix 110 to prepare a first mix solution, and casting the first mix solution to produce a cast film.

According to one embodiment of the present disclosure, a polyimide-based resin solution may be used as the resin solution for forming the light-transmitting matrix 110.

More specifically, the method of manufacturing the optical film 100 according to an embodiment of the present disclosure includes preparing a polyimide-based resin powder, dissolving the polyimide-based resin powder in a first solvent to obtain a polyimide-based resin solution, preparing a filler dispersion, and mixing the filler dispersion with the polyimide-based resin solution to prepare a first mix solution.

The filler dispersion may be prepared, for example, by dispersing the filler 120 in a second solvent.

DMAc (N,N-dimethylacetamide) may be used as the first solvent. DMAc (N,N-dimethylacetamide) or methyl ethyl ketone (MEK) may be used as the second solvent, but one embodiment of the present disclosure is not limited thereto, and other known solvents as the first solvent and the second solvent may be used.

According to one embodiment of the present disclosure, to improve the dispersibility of the filler 120, for example, the pH of the first mix solution may be adjusted. For example, the pH of the first mix solution may be adjusted to the range of 5 to 7. Accordingly, aggregation or agglomeration of the filler 120 may be prevented.

Next, the first mix solution is cast, dried and heat-treated to form an optical film 100. According to one embodiment of the present disclosure, the film formed by casting the first mix solution may be referred to as a “cast film” and the film produced by drying and heat-treating the cast film may be referred to as an “optical film 100”. The cast film can be referred to as an “uncured film”.

In addition, convection may be prevented during drying and heat treatment of the cast film formed by casting, so that the filler 120 may be oriented in a certain direction.

Specifically, when convection is generated inside the cast film that is dried using heat, the orientation of the filler 120 may decrease. Thus, the cast film may be allowed to be dried slowly to prevent convection. For example, drying of the cast film may be performed while raising the temperature from 80° C. to 120° C. at a rate of 1° C./1 minute. When drying is performed over a certain level, the orientation of the filler 120 may be fixed.

Hereinafter, the present disclosure will be described in more detail with reference to Preparation Example and Example. However, the following Preparation example and Example should not be construed as limiting the scope of the present disclosure.

### Preparation Example 1: Preparation of Polymer-Imide-Based Polymer Solid

719.104 g of N,N-dimethylacetamide (DMAc) was charged in a 1 L reactor equipped with a stirrer, a nitrogen injector, a dropping funnel, a temperature controller, and a cooler while the reactor was purged with nitrogen. Then, the temperature of the reactor was adjusted to 25° C., 54.439 g (0.17 mol) of bis(trifluoromethyl)benzidine (TFDB) was dissolved therein and the temperature of the solution was maintained at 25° C. 13.505 g (0.046 mol) of biphenyl-tetracarboxylic acid dianhydride (BPDA) was further added thereto and completely dissolved therein by stirring for 3 hours, and 9.063 g (0.020 mol) of 4,4′-(hexafluoroisopropylidene)diphthalic anhydride (6FDA) was further added thereto and completely dissolved therein. The reactor temperature was lowered to 10° C., and 21.053 g (0.104 mol) of terephthaloyl chloride (TPC) was further added thereto and allowed to react at 25° C. for 12 hours to obtain a polymer solution having a solid content of 12 wt %.

11.54 g of pyridine and 14.90 g of acetic anhydride were added to the obtained polymer solution, stirred for 30 minutes, heated at 80° C., stirred at the same temperature for 1 hour to allow a reaction to occur, and allowed to cool to room temperature. 20 L of methanol was added to the obtained polymer solution to precipitate a solid and the precipitated solid was filtered, pulverized, washed with 2 L of methanol, and dried under vacuum at 100° C. for 6 hours or longer to prepare a polyimide-based polymer solid as a powder. The prepared polyimide-based polymer solid was a polyamide-imide polymer solid.

### Example 1

723.46 g of DMAc (first solvent) was added to a 1 L reactor and the reactor was stirred for a certain period of time while the temperature of the reactor was maintained at 10° C. Then, 110 g of polyamide-imide (polyimide-based resin powder) prepared as the solid powder in Preparation Example 1 was added to the reactor, stirred for 1 hour, and heated to 25° C. to prepare a polyimide-based resin solution.

Then, the prepared liquid polyimide resin solution was slowly added to 55 g of an alumina hydrate filler dispersion prepared by dispersing an alumina hydrate-based filler 120 having an average particle diameter of about 4 nm and an average length of about 1,500 nm in a DMAc (N,N-dimethylacetamide, second solvent) solution using a cylinder pump for 1 hour to prepare a first mix solution containing the silica dispersion and the polyimide resin solution.

The pH of the first mix solution was 8 or higher when measured immediately after preparing the first mix solution. In order to improve the alignment characteristics of the filler 120, a weak acid such as acetic acid was added to the first mix solution to adjust the pH of the first mix solution to be within the range of 5 to 7. The first mix solution thus prepared was a polyimide-based resin solution in which the filler 120 having a fiber shape was dispersed.

The obtained first mix solution was cast. A casting substrate was used for casting. At this time, there is no particular limitation on the type of the casting substrate. The casting substrate may be a glass substrate, a stainless steel (SUS) substrate, a Teflon substrate, or the like. According to one embodiment of the present disclosure, a glass substrate was used as the casting substrate.

Specifically, the cast film was produced by slowly drying in a hot air oven at 80° C. up to 120° C. at a rate of 1° C./min for about 40 minutes to maintain the orientation of the filler 120. Then, the produced film was peeled off of the glass substrate and fixed to a frame with pins.

The frame to which the optical film was fixed was slowly heated in a vacuum oven from 100° C. to 280° C. for 2 hours, cooled slowly and separated from the frame to obtain an optical film. The optical film was heated again at 250° C. for 5 minutes.

As a result, an optical film 100 having a thickness of 50 μm and including a light-transmitting matrix 110 and a silica-based filler 120 dispersed in the light-transmitting matrix 110 was completed.

### Examples 2 and 3

The optical films 100 were produced under the conditions of Table 1 in the same manner as in Example 1 and were respectively referred to as “Examples 2 and 3”.

### Comparative Examples 1 to 4

The optical films 100 were produced under the conditions of Table 1 in the same manner as in Example 1 and were respectively referred to as “Comparative Examples 1 to 4”.

TABLE 1

| | Light-transmitting matrix (molar ratio) | | | | | Con- |
|---|---|---|---|---|---|---|
| | Di- | | | Dicarbonyl | Type | tent of |
| | amine | Dianhydride | | compound | of | filler |
| Item | TFDB | 6FDA | BPDA | TPC | filler | (PHR) |
| Example 1 | 100 | 12 | 27 | 61 | Filler | 5 |
| | | | | | 1 | |
| Example 2 | 100 | 12 | 27 | 61 | Filler | 10 |
| | | | | | 1 | |
| Example 3 | 100 | 12 | 27 | 61 | Filler | 15 |
| | | | | | 1 | |
| Comparative | 100 | 12 | 27 | 61 | Not- | 0 |
| Example 1 | | | | | added | |
| Comparative | 100 | 12 | 27 | 61 | Filler | 10 |
| Example 2 | | | | | 2 | |
| Comparative | 100 | 12 | 27 | 61 | Filler | 2.5 |
| Example 3 | | | | | 1 | |
| Comparative | 100 | 12 | 27 | 61 | Filler | 51 |
| Example 4 | | | | | 1 | |

In Table 1, Filler 1 refers to a nanowire having an aspect ratio of 375 and Filler 2 refers to a nanoparticle having a particle diameter of 20 nm. Specifically, the length of Filler 1 is 1.5 μm and the diameter of Filler 1 is 4 nm.

In Table 1, the molar ratio represents a molar ratio of the corresponding component with respect to the total 100 moles of diamine.

In Table 1, PHR represents per hundred resin meaning the weight (g) of the filler with respect to 100 (g) of the weight of the light-transmitting matrix. Specifically, PHR according to an embodiment of the present disclosure represents the weight (g) of the filler added per 100 (g) of the weight of the solid of the polyimide-based polymer.

The physical properties of the optical films produced in Examples 1 and 3 and Comparative Examples 1 to 4 were measured as follows.

### (1) Measurement of Modulus

The modulus of the optical film was measured in accordance with ASTM D885 using a universal tensile tester (MODEL 5967) from Instron Corp.
Standards of measurement within three hours after film production
Load Cell 30 kN, Grip 250 N
Specimen size 10 mm×50 mm, Tensile speed 25 mm/min

### (2) Measurement of Yield Tensile Strength

Stress at the contact point formed when offsetting the modulus of the S-S curve by 0.2%
Measured using universal tensile tester (MODEL 5967) from Instron Corp.

### (3) Measurement of Tensile Load

Stress when 1% strain is reached
Measured using universal tensile tester (MODEL 5967) from Instron Corp.

### (4) Measurement of Compressive Load

Stress when the grip is returned to the initial position after 1% strain is obtained
Measured using universal tensile tester (MODEL 5967) from Instron Corp.

### (5) Measurement of Strain 2

Strain variation (%) of the specimen after 5 cycles (%)
Measured using universal tensile tester (MODEL 5967) from Instron Corp.

### (6) Measurement of Recovery Rate (Cycle Test)

The recovery rate upon repeated tension-compression of the optical film was measured using a universal tensile tester (MODEL 5967) from Instron Corp.
Load Cell 30 kN, Grip 250 N.
Specimen size 10 mm×50 mm, cycle strain 1%, cycle speed 30% strain/min, 5 cycles (elongation-compression)

The results of measurement are shown in Table 2 below.

TABLE 2

| | | Yield | | | | | | | | |
|---|---|---|---|---|---|---|---|---|---|---|
| | | tensile | Tensile | Compressive | Total | Stress | Strain | Strain | Strain | |
| | Modulus | strength | load | load | load | hysteresis | 1 | 2 | Hysteresis | S/S |
| Item | (GPa) | (MPa) | (N) | (N) | (N) | (%) | (%) | (%) | (%) | index |
| Example 1 | 8.12 | 125 | 44.05 | 3.28 | 47.33 | 6.930 | 0 | 0.085 | 8.500 | 0.665 |
| Example 2 | 9.98 | 130 | 46.20 | 3.40 | 49.60 | 6.855 | 0 | 0.087 | 8.700 | 0.621 |
| Example 3 | 11.3 | 144 | 55.50 | 4.47 | 59.97 | 7.454 | 0 | 0.091 | 9.100 | 0.671 |
| Comparative | 6.51 | 105 | 30.10 | 1.75 | 31.85 | 5.495 | 0 | 0.077 | 7.700 | 0.509 |
| Example 1 | | | | | | | | | | |
| Comparative | 6.73 | 110 | 31.20 | 1.88 | 33.08 | 5.683 | 0 | 0.081 | 8.100 | 0.492 |
| Example 2 | | | | | | | | | | |
| Comparative | 7.15 | 110 | 35.00 | 2.10 | 37.10 | 5.660 | 0 | 0.079 | 7.900 | 0.513 |
| Example3 | | | | | | | | | | |
| Comparative | 15.50 | 158 | 61.70 | 5.10 | 66.80 | 7.635 | 0 | 0.110 | 11.00 | 0.482 |
| Example4 | | | | | | | | | | |

As can be seen from the results of measurement in Table 2, the optical film (100) according to an embodiment of the present disclosure has an S/S index of 0.6 or more.

1. An optical film comprising:
a light-transmitting matrix; and
a filler dispersed in the light-transmitting matrix,
the optical film having an S/S index of 0.6 or more,
wherein the S/S index is calculated in accordance with Equation 1 below:
S/S index=stress hysteresis/strain hysteresis [Equation 1]
wherein the stress hysteresis is calculated in accordance with Equation 2 below:
Stress hysteresis=[maximum compressive load/total load]×100 [Equation 2]
wherein the strain hysteresis is calculated in accordance with Equation 3 below:
Strain hysteresis=[strain 2−strain 1]×100 [Equation 3]
wherein the maximum compressive load is a maximum compressive load required for the optical film to return to an original state after elongation, and
the total load (N) is a sum of a tensile load and a compressive load,
wherein the tensile load is a load required for the optical film to be elongated to a specific strain, and
the compressive load is a load required for the optical film to return to an original state after elongation,
the strain 1 is a strain before the optical film is deformed, and
the strain 2 is a strain after the optical film is deformed.

2. The optical film according to claim 1, wherein the filler has a fiber or filament shape.

3. The optical film according to claim 1, wherein the filler has an aspect ratio of 5 to 2,500,
wherein the aspect ratio is a ratio of a length of the filler to a diameter of the filler.

4. The optical film according to claim 1, wherein the filler has a length of 0.1 to 5 μm.

5. The optical film according to claim 1, wherein the filler has a diameter of 2 to 20 nm.

6. The optical film according to claim 1, wherein a content of the filler is 3 to 50 PHR with respect to 100 g of the light-transmitting matrix.

7. The optical film according to claim 1, wherein the optical film has a yield tensile strength of 90 to 160 MPa.

8. The optical film according to claim 1, wherein the optical film has a modulus of 4.0 to 15 GPa.

9. The optical film according to claim 1, wherein the light-transmitting matrix comprises at least one of an imide repeating unit or an amide repeating unit.

10. A display device comprising:
a display panel; and
the optical film according to claim 1 disposed on the display panel.
